(19) United States
(12) Patent Application Publication
(10) Pub. No.: US 2024/0265154 A1
(43) Pub. Date: Aug. 8, 2024

(54) ENLARGING THE SCOPE OF PHYSICAL OBJECT MODELS

(71) Applicant: INTERNATIONAL BUSINESS MACHINES CORPORATION, ARMONK, NY (US)

(72) Inventors: Zachary A. Silverstein, Georgetown, TX (US); Logan Bailey, Atlanta, GA (US); Suman Patra, Kolkata (IN); Fang Lu, Billerica, MA (US)

(21) Appl. No.: 18/166,352

(22) Filed: Feb. 8, 2023

(51) Int. Cl. G06F 30/10; B33Y 50/00; G06T 17/00

(52) U.S. Cl. CPC G06F 30/10; B33Y 50/00; G06T 17/00

(57) ABSTRACT

A computer-implemented method, a computer system and a computer program product customize a model of a physical object to account for the surrounding environment. The method includes identifying an interaction with a physical object in a surrounding environment. The method also includes obtaining a model of the physical object. The method further includes capturing an image of the physical object in the surrounding environment. In addition, the method includes determining that the surrounding environment contains barriers to the interaction with the physical object. Lastly, the method includes generating an enhanced model of the physical object, wherein the enhanced model includes a representation of the surrounding environment.

### BACKGROUND

Embodiments relate generally to the field of modelling of physical objects and spaces, and more specifically, to customizing a model of a physical object to account for the surrounding environment.

It may be common for humans to interact with devices that are extremely large or hard to access, e.g., air conditioning or other HVAC machines within a home or office, automobiles or other vehicles, refrigerators or other appliances in a home or office space, and other similar items. It may also be common for these items to be installed in condensed, or hard to reach, locations in homes or offices, and repair or maintenance may need to be completed in this context. These sorts of items may also be modelled using known information from the manufacturer, such as a service manual or other documentation, as a source and the resulting model may be used to provide a representation of the item to a user, for example a printed model from a three-dimensional (3D) printing system.

### SUMMARY

An embodiment is directed to a computer-implemented method for customized modelling of a physical object to account for a surrounding environment. The method may include identifying an interaction with the physical object in the surrounding environment. The method may also include obtaining a model of the physical object. The method may further include capturing an image of the physical object in the surrounding environment. In addition, the method may include determining that the surrounding environment contains barriers to the interaction with the physical object. Lastly, the method may include generating an enhanced model of the physical object, where the enhanced model includes a representation of the surrounding environment.

In another embodiment, the generating the enhanced model may include creating a physical representation of the physical object and the surrounding environment using a three-dimensional (3D) printing system.

In a further embodiment, the enhanced model may include a distinct indicator, where the distinct indicator may be associated with one or more of: the barriers to the interaction, an area on the physical object to be accessed in the interaction, and dangerous parts of the physical object.

In yet another embodiment, the method may include monitoring user interactions with the enhanced model and updating the enhanced model of the physical object and the surrounding environment based on the user interactions.

In another embodiment, a machine learning model that recognizes an inaccessibility of a device based on a task identification and current images of the device and a surrounding area may be used for determining that the surrounding environment contains the barriers to the interaction with the physical object.

In a further embodiment, the enhanced model may be an augmented reality representation of the physical object and the surrounding environment.

In yet another embodiment, the model of the physical object may be a digital twin instance from a digital twin simulation.

In addition to a computer-implemented method, additional embodiments are directed to a computer system and a computer program product for customized modelling of a physical object to account for the surrounding environment.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 depicts a block diagram of an example computer system in which various embodiments may be implemented.

FIG. 2 depicts a flow chart diagram for a process that customizes a model of a physical object to account for the surrounding environment according to an embodiment.

### DETAILED DESCRIPTION

It may be common in today's residential and commercial buildings, or even in outdoor spaces, for devices that are extremely large to be installed in condensed spaces that are hard to access. The surrounding environment in these cases may present barriers and other difficulties to service technicians or other people to do routine and important tasks such as repair or maintenance on these devices, which may include air conditioning or other HVAC machines within a home or office, automobiles or other vehicles, refrigerators or other appliances in a home or office space, and other similar items. An end user or service technician may not be familiar with the details of such items when they encounter a device in a surrounding environment, and since the space may be condensed or include some barriers, that person may not have the ability to look directly at a surface or other area that may need to be accessed. In addition to access to the device, it may also be difficult to easily maneuver around the space or manipulate items such as tools in the space.

It may therefore be useful to provide a method or system that can understand both the device to which such a user needs access and also the surrounding environment and then give the user a likely template for how this interaction might work by modelling the device and environment and provide a representation to the user, for example a three-dimensional (3D) printed physical model or an augmented reality (AR) virtual representation of the device and environment. Such a method or system may allow a user to gain tactile object familiarity prior to attempting to access or manipulate a device in a condensed space that may be difficult to access or visually inaccessible. Such a method or system may also improve the efficiency of various modelling systems by accounting for the surrounding environment in customizing models of devices for the purpose of service, maintenance, or other interactions between humans and devices.

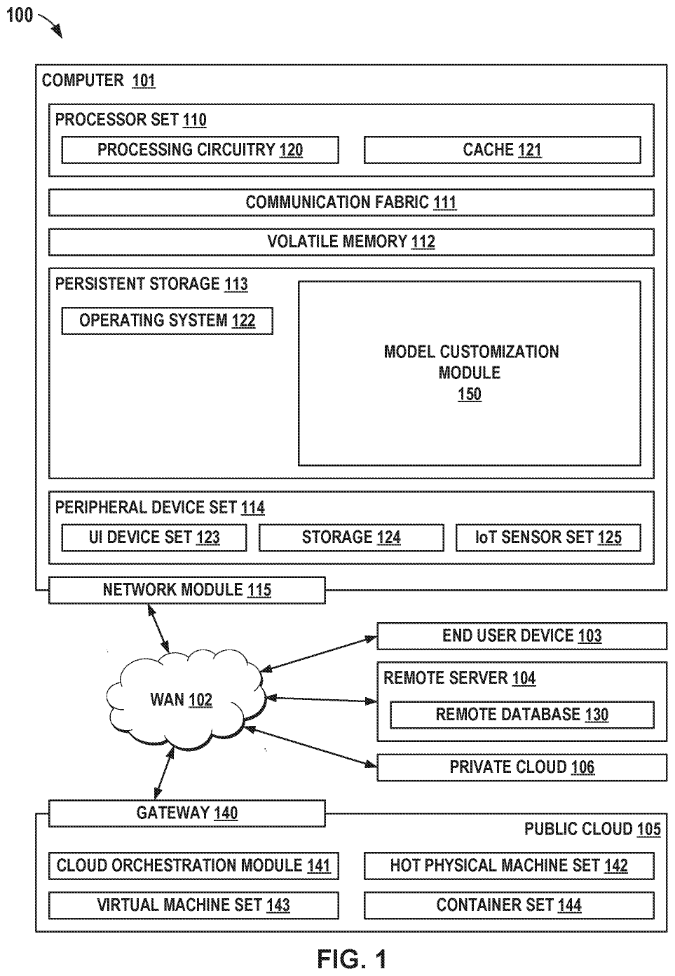

Referring to FIG. 1, computing environment 100 contains an example of an environment for the execution of at least some of the computer code involved in performing the inventive methods, such as model customization module 150. In addition to model customization module 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and model customization module 150, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in model customization module 150 in persistent storage 113.

Communication fabric 111 is the signal conduction paths that allow the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in model customization module 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101) and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of VCEs will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Computer environment 100 may be used to customize a model of a physical object to account for the surrounding environment. In particular, the model customization module 150 may identify an interaction or task that needs to be performed on a physical object in a surrounding environment, such as maintenance or repair of a computer or other device on a desk. The module 150 may obtain a model of the physical object of the interaction or task, which may already be stored in a database or other storage or may be generated based on information that may include a service manual or other documentation from a manufacturer of a product or other source. An existing model may have specific parts that may be identified by the user or by the module 150 as important to the identified task or interaction to be completed. For instance, if the system knows that the cover of the computer must be removed to complete the task or interaction, the module 150 may indicate the specific location of the screws that hold the cover to the rest of the computer. In addition, the module 150 may capture information about the surrounding environment, which may include images of the environment. In the example of the computer on the desk, the user that may be performing the task or interacting with the computer may take several images of the computer from many angles within the environment and upload the images to the module 150. From the images, conditions that may be barriers to the interaction or task may be identified. For instance, the space between the object and any walls or other obstructions may be captured in the image. It may also be determined that a user performing the task or interaction is not able to see specific parts on the object that may need to be accessed to complete the task or interaction. From the information about the object and the surrounding environment, the module 150 may use modelling techniques to generate a new model of the object that includes the environment, where for example, parts of the physical object may be marked with an indicator, such as a special color or pattern, if they are determined to be in a difficult location to access. It should be noted that either or both of the obtained model of the physical object and the generated new model may be virtual, where the user may interact with the model in an augmented reality (AR) environment using appropriate equipment, or may be physical, where a 3D printing system may be used to create a physical representation of both the object and the surrounding environment, where a user could gain tactile familiarity with the interaction or task prior to attempting the same interaction or task in the environment.

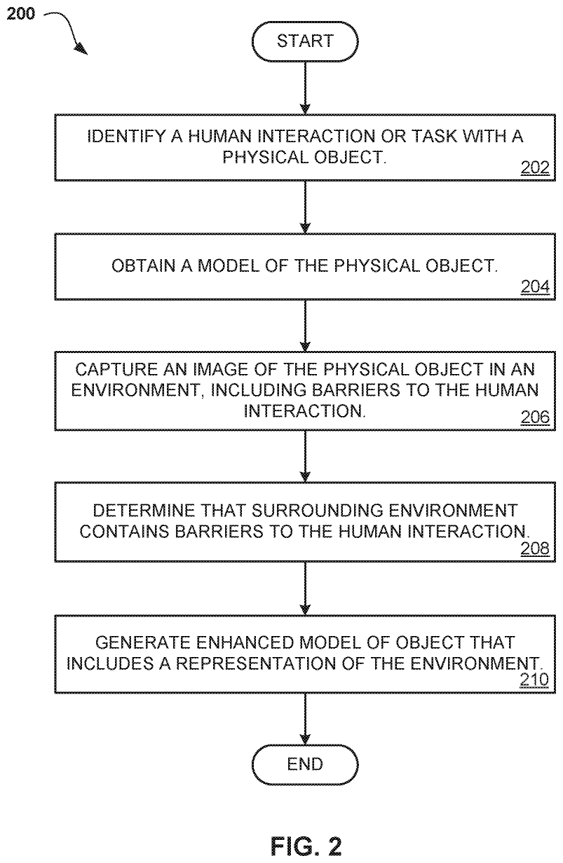

Referring to FIG. 2, an operational flowchart illustrating a process 200 that customizes a model of a physical object to account for the surrounding environment is depicted according to at least one embodiment. At 202, a task or interaction between a human and a physical object may be identified. It should be noted that an exact form of the input to the module 150 is not limited, e.g., a user may indicate the task or interaction to the module 150 through voice or text input or the module 150 may monitor an environment for audible or visual input from a user using a microphone or camera. It is only required that a physical object is identified in addition to the identification of the task or interaction. Optionally at this step, the user may indicate that the surrounding environment presents barriers to the task or interaction, e.g., the user may say or type that “I need to replace the motor in this air conditioner, but the space around the unit is too condensed for me to be able to work or use my tools,” and the module 150 may note this input for later in the process.

In the case of video or audio capture of human activity, whether the user initiates the input or the module 150 monitors an environment and gathers the input, it should be noted that all collection of information from a user or any video, audio or text that may personally identify a human user or is sensitive in any other way requires the informed consent of all people whose information may be collected and analyzed by model customization module 150. Consent may be obtained in real time or through a prior waiver or other process that informs a subject that their information may be captured by a device or other process and that the information may be used to identify tasks or interactions with a physical object in the environment and provide a model of the physical object that includes the surrounding environment, as will be described in detail below. The information owner is free to decide at any time to revoke consent for use of sensitive information as these settings are permanently retained to keep the model customization module 150 updated with the latest information and also allow the owner of the information complete control over their informed consent to use sensitive information in the process described herein. The consent described here may also refer to allowing some, or any, data relating to the information owner from being sent to a local server, cloud server or any other location. The owner has complete control on the transmission of information that may be sensitive or personally identify the owner of the information. It should be noted that in addition to consent with respect to personally identifying information, consent may also be requested and received from any user with respect to devices that may be owned by the user, such as augmented reality (AR) equipment or 3D printing systems that may be used as described below. As with the information described above, this consent is also revocable at any time should conditions change for any reason.

At 204, a model of the physical object may be obtained. The model may be already stored in a database or other storage location that may be accessible to the system or alternatively, may be generated by the module 150 using information from the manufacturer, e.g., a service manual or product marketing materials such as a brochure or a captured image from an advertisement. At this step, the physical object may be simply reproduced in whatever detail may be available at the moment and it is not necessary for the user to be able to interact with the model. One of ordinary skill in the art would recognize that this model may be virtual, such as a replication of the physical object on a computer screen or an augmented reality (AR) projection that may be seen with appropriate equipment, or the model may be physical, such as a 3D representation of the object that has been printed from a 3D printer.

In an embodiment, the initial model of the physical object may be part of a digital twin simulation. A digital twin is a virtual model designed to accurately reflect a physical object. The object being studied, e.g., an air conditioner or a computer, may be outfitted with various sensors related to vital areas of functionality which produce data about different aspects of the physical object's performance, such as battery level or other engine performance metrics. This data may then be relayed to a processing system and applied to the digital copy. Once informed with such data, the virtual model can be used to run simulations, study performance issues and generate possible improvements, all with the goal of generating valuable insights, all of which may then be applied back to the original physical object.

Although simulations and digital twins both utilize digital models to replicate various processes, a digital twin is actually a virtual environment and while a simulation typically studies one particular process, a digital twin can itself run any number of useful simulations in order to study multiple processes. Digital twins are designed around a two-way flow of information that first occurs when object sensors provide relevant data to the system processor and then happens again when insights created by the processor are shared back with the original source object. By having better and constantly updated data related to a wide range of areas, along with the added computing power that accompanies a virtual environment, digital twins are able to study more issues from far more vantage points than standard simulations and have greater ultimate potential to improve products and processes. Examples of the types of digital twins include component twins, which are the basic unit of digital twin or the smallest example of a functioning component, parts twins, which pertain to components of slightly less importance, asset twins, which study the interaction between components that work together, system (or unit) twins, which enable you to see how different assets come together to form an entire functioning system, and process twins, which are the macro level of magnification and reveal how systems work together to create an entire production facility, which may help determine the precise timing schemes that ultimately influence overall effectiveness.

It is important to note that the source of the information for the modelling of the physical object at this step is not required to be an existing model or information about the physical object. In another embodiment, the model of the physical object may be created through a rough sketch by any user of the device, including a verbal description of the device or surrounding environment provided by any user through a microphone that may then be transcribed into text, or an initial image of the device in the current surrounding environment or another context, e.g., a friend or neighbor may have the same refrigerator installed in their home or office. Alternatively, the user may have experience with the task or interaction on the same or other physical objects and be able to provide this personal knowledge in either identifying the task or interaction or obtaining the model of the physical object, which may then be used to create a model of the physical object.

This additional information, or any prior knowledge about the physical object or the task or interaction, may also be used at this step or later in the process to add a distinct indicator to either the model at this step or later to the enhanced model that may show dangerous parts in or on the object, e.g., the evaporator and condenser coils where freon flows on the inside and outside of a refrigerator, or perhaps specific screws, plugs or other parts or areas on or in the physical object that the user may be likely to interact with in the course of the task or interaction. Such a distinct indicator may take the form of a specific color or pattern or other method of distinctly indicating to a user the part or area being marked and the indicator may be keyed to the indication that the process may want to send to the user (a potential barrier to the interaction, an area on the physical object to be accessed in the interaction, dangerous parts of the physical object, etc).

At 206, one or more images of the physical object in the surrounding object may be captured, where the one or more images include barriers to the task or interaction. As with the identification of the task or interaction, the images may be captured by the user and uploaded to the system or the module 150 may use an appropriate device and capture images of the physical object in its surrounding environment. If the user indicated one or more barriers to the task or interaction in 202, then the images that are captured at this step may focus on specific areas that relate to the one or more barriers. In this case, the module 150 may indicate to the user which images should be captured and uploaded to the system to improve modelling of the physical object and the surrounding environment.

At 208, the model customization module 150 may determine that the surrounding environment may contain a barrier to the interaction. The barrier may have been indicated by the user in identifying the task or interaction or may be determined by the module 150 from the images that may be captured in the prior step. A non-exhaustive list of possible barriers to the interaction may include specific characteristics of the physical object (e.g., whether the object is a computer, a refrigerator or HVAC unit), the dimensions of the physical object, proximity of the physical object, including specific parts or areas that are required for access in the interaction, to a wall or other fixed obstructions in the surrounding environment.

In an embodiment, a supervised machine learning model may be trained to predict whether a barrier to the identified task or interaction exists based on images of a physical object and its surrounding area. One or more of the following machine learning algorithms may be used: logistic regression, naive Bayes, support vector machines, deep neural networks, random forest, decision tree, gradient-boosted tree, multilayer perceptron. In an embodiment, an ensemble machine learning technique may be employed that uses multiple machine learning algorithms together to assure better classification when compared with the classification of a single machine learning algorithm. In this embodiment, training data for the model may include any prior tasks or interactions with the physical object in the current surrounding area or any location for which data exists. The training data may take the form of video or audio of users completing tasks or interacting with the physical object. The training data may be collected from a single instance of a human interacting with a specific physical object in the same way as the identified task or interaction or by collecting data from many instances of humans performing the same task or interaction with the physical object in similar or different surrounding areas. The prediction results may be stored in a database so that the data is most current, and the output would always be up to date.

At 210, a new enhanced model of the physical object that includes a model of the surrounding environment may be generated. This may include physically mapping the surrounding environment using computer vision techniques, e.g., object recognition, or other methods to generate a complete picture of accessibility barriers. The distance between objects, such as a surface on the physical object and an adjoining wall, may be measured by the module 150 and this distance may be incorporated into the enhanced model such that an accurate replica of the surrounding environment may be generated for the user. The accuracy and detail of the enhanced model may be critical to the intended use of the enhanced model by the user of practicing the task or interaction that has been identified on a physical version of the model, or in an augmented reality environment on a virtual model. The scope of the initial model, which is only of the physical object, is enlarged by the enhanced model to account for the surrounding environment. If distinct indicators of a potential barrier to the interaction, an area on the physical object to be accessed in the interaction or dangerous parts of the physical object were included in the original model of the physical object, these indicators may be preserved or indicators may be added at this step to assist with the utility of the enhanced model.

In an embodiment, the module 150 may be able to determine from the images of the physical object, in conjunction with available information about the physical object, that changes may be made to the physical object in order to overcome predicted barriers to the task or interaction. For instance, it may be determined that a microwave oven that is built into the cabinets but can be pulled out partially to overcome predicted barriers to the interaction. In such a case, the enhanced model may be altered to account for the possibility of movement, along with distinct indicators such as those mentioned above to show that an alteration of the physical object or surrounding environment has been made. Other alterations to the physical object may include realistic widget information, for instance removing screws or other parts should they not be relevant to the task or interaction or necessary to providing a realistic experience to the user for practicing the task or interaction.

Included at this step may be a feedback mechanism, whereby the interaction of the user with the enhanced model may be recorded and used to refine the enhanced model. Also included at this step is the ability of the user to make manual decisions about the enhanced model such as whether or not the indicators of dangerous parts, relevant areas or other important aspects are correct. The interaction of such users with the enhanced model would be monitored and updates to the enhanced, including the mentioned changes to the indicators, may be made based on the user interactions.

One of ordinary skill in the art will recognize that appropriate files may be generated at this step, such that a virtual model could be stored in relevant indexed storage such as a database and also sent to a 3D printer system using a file format that native to stereolithography CAD software, e.g., STL. The virtual model may also be saved in file formats that are suitable for augmented reality systems for later retrieval by users as it is not required for the user to immediately utilize the enhanced model in practicing the task or interaction. The enhanced model may further be saved for use in later interactions or tasks with different users or may even be used in the machine learning model described above to predict the existence of barriers with respect to later interactions between users and physical objects.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A computer-implemented method for customized modelling of a physical object to account for a surrounding environment, the method comprising:
identifying an interaction with the physical object in the surrounding environment;
obtaining a model of the physical object;
capturing an image of the physical object in the surrounding environment;
determining that the surrounding environment contains barriers to the interaction with the physical object; and
generating an enhanced model of the physical object, wherein the enhanced model includes a representation of the surrounding environment.

2. The computer-implemented method of claim 1, wherein the generating the enhanced model further comprises creating a physical representation of the physical object and the surrounding environment using a three-dimensional (3D) printing system.

3. The computer-implemented method of claim 1, wherein the enhanced model includes a distinct indicator, wherein the distinct indicator is associated with one or more of: the barriers to the interaction, an area on the physical object to be accessed in the interaction, and dangerous parts of the physical object.

4. The computer-implemented method of claim 1, further comprising:
monitoring user interactions with the enhanced model; and
updating the enhanced model of the physical object and the surrounding environment based on the user interactions.

5. The computer-implemented method of claim 1, wherein a machine learning model that recognizes an inaccessibility of a device based on a task identification and current images of the device and a surrounding area is used for determining that the surrounding environment contains the barriers to the interaction with the physical object.

6. The computer-implemented method of claim 1, wherein the enhanced model is an augmented reality representation of the physical object and the surrounding environment.

7. The computer-implemented method of claim 1, wherein the model of the physical object is a digital twin instance from a digital twin simulation.

8. A computer system for customized modelling of a physical object to account for a surrounding environment, the computer system comprising:
one or more processors, one or more computer-readable memories, and one or more computer-readable storage media;
program instructions, stored on at least one of the one or more computer-readable storage media for execution by at least one of the one or more processors via at least one of the one or more memories, to identify an interaction with the physical object in the surrounding environment;
program instructions, stored on at least one of the one or more computer-readable storage media for execution by at least one of the one or more processors via at least one of the one or more memories, to obtain a model of the physical object;
program instructions, stored on at least one of the one or more computer-readable storage media for execution by at least one of the one or more processors via at least one of the one or more memories, to capture an image of the physical object in the surrounding environment;
program instructions, stored on at least one of the one or more storage media for execution by at least one of the one or more processors via at least one of the one or more memories, to determine that the surrounding environment contains barriers to the interaction with the physical object; and
program instructions, stored on at least one of the one or more computer-readable storage media for execution by at least one of the one or more processors via at least one of the one or more memories, to generate an enhanced model of the physical object, wherein the enhanced model includes a representation of the surrounding environment.

9. The computer system of claim 8, wherein the program instructions to generate the enhanced model create a physical representation of the physical object and the surrounding environment using a three-dimensional (3D) printing system.

10. The computer system of claim 8, wherein the enhanced model includes a distinct indicator, wherein the distinct indicator is associated with one or more of: the barriers to the interaction, an area on the physical object to be accessed in the interaction, and dangerous parts of the physical object.

11. The computer system of claim 8, further comprising:
program instructions, stored on at least one of the one or more computer-readable storage media for execution by at least one of the one or more processors via at least one of the one or more memories, to monitor user interactions with the enhanced model; and
program instructions, stored on at least one of the one or more computer-readable storage media for execution by at least one of the one or more processors via at least one of the one or more memories, to update the enhanced model of the physical object and the surrounding environment based on the user interactions.

12. The computer system of claim 8, wherein the program instructions to determine that the surrounding environment contains the barriers to the interaction with the physical object use a machine learning model that recognizes an inaccessibility of a device based on a task identification and current images of the device and a surrounding area.

13. The computer system of claim 8, wherein the enhanced model is an augmented reality representation of the physical object and the surrounding environment.

14. The computer system of claim 8, wherein the model of the physical object is a digital twin instance from a digital twin simulation.

15. A computer program product for customized modelling of a physical object to account for a surrounding environment, the computer program product comprising:
one or more computer-readable storage media;
program instructions, stored on at least one of the one or more computer-readable storage media, to identify an interaction with the physical object in the surrounding environment;
program instructions, stored on at least one of the one or more computer-readable storage media, to obtain a model of the physical object;
program instructions, stored on at least one of the one or more computer-readable storage media, to capture an image of the physical object in the surrounding environment;
program instructions, stored on at least one of the one or more computer-readable storage media, to determine that the surrounding environment contains barriers to the interaction with the physical object; and
program instructions, stored on at least one of the one or more computer-readable storage media, to generate an enhanced model of the physical object, wherein the enhanced model includes a representation of the surrounding environment.

16. The computer program product of claim 15, wherein the program instructions to generate the enhanced model create a physical representation of the physical object and the surrounding environment using a three-dimensional (3D) printing system.

17. The computer program product of claim 15, wherein the enhanced model includes a distinct indicator, wherein the distinct indicator is associated with one or more of: the barriers to the interaction, an area on the physical object to be accessed in the interaction, and dangerous parts of the physical object.

18. The computer program product of claim 15, further comprising:
program instructions, stored on at least one of the one or more computer-readable storage media, to monitor user interactions with the enhanced model; and
program instructions, stored on at least one of the one or more computer-readable storage media, to update the enhanced model of the physical object and the surrounding environment based on the user interactions.

19. The computer program product of claim 15, wherein the program instructions to determine that the surrounding environment contains the barriers to the interaction with the physical object use a machine learning model that recognizes an inaccessibility of a device based on a task identification and current images of the device and a surrounding area.

20. The computer program product of claim 15, wherein the enhanced model is an augmented reality representation of the physical object and the surrounding environment.
